(19) United States
(12) Patent Application Publication
(10) Pub. No.: US 2026/0247950 A1
(43) Pub. Date: Aug. 20, 2026

(54) SEMICONDUCTOR DEVICE

(71) Applicant: Socionext Inc., Kanagawa (JP)

(72) Inventors: Hirotaka TAKENO, Yokohama (JP); Atsushi OKAMOTO, Yokohama (JP); Wenzhen WANG, Yokohama (JP)

(21) Appl. No.: 19/647,044

(22) Filed: Apr. 14, 2026

Related U.S. Application Data
(63) Continuation of application No. PCT/JP2023/037783, filed on Oct. 19, 2023.

(51) Int. Cl. H10W 20/41; H10D 84/85; H10W 20/20; H10W 20/43

(52) U.S. Cl. CPC H10W 20/427; H10D 84/851; H10W 20/2134; H10W 20/43; H10W 20/435

(57) ABSTRACT

A semiconductor device includes a substrate, a first cell including a first power supply line, a first CFET including a first transistor disposed on a second surface of the substrate, and a second transistor disposed above the first transistor, a first conductive wall extending in a first direction, and a first interconnect extending in the second direction and connected to the first transistor, and a second cell including a second power supply line extending in the first direction on a first surface, a second CFET including a third transistor disposed on the second surface, and a fourth transistor disposed above the third transistor, a second conductive wall extending in the first direction, and a second interconnect extending in the second direction and connected to the third transistor, wherein the first interconnect and the second interconnect are arranged in a staggered manner in the first direction.

### CROSS-REFERENCE TO RELATED APPLICATIONS

This application is a continuation application of International Application No. PCT/JP2023/037783, filed on October 19, 2023, and designated the U.S., the entire contents of which are incorporated herein by reference.

### BACKGROUND OF THE INVENTION

The disclosures herein relate to semiconductor devices.

There is a technology called CFET (Complementary Field Effect Transistor) which forms a CMOS (Complementary Metal-Oxide-Semiconductor) by stacking transistors in a direction perpendicular to a substrate. With the use of CFETs, an area of a CMOS basic cell is significantly reduced, and a semiconductor device is downsized. In a technology called BS-PDN (Backside Power Delivery Network) which supplies a power supply voltage to a circuit on a front surface of a semiconductor substrate from a back surface of the substrate, a configuration is used in which a Through Silicon Via (TSV) penetrating the substrate is directly connected to a source/drain of a transistor. There is a technology called a power wall in which a conductive wall is formed over the height of the upper and lower transistors of the CFET to supply power to each transistor.

In a circuit that supplies power to a CFET via a power wall, how to arrange transistors and respective interconnects has not been studied in detail. The present disclosure aims to provide a semiconductor device having a circuit for supplying power to the CFET with a conductive wall perpendicular to a substrate, and having a structure capable of reducing a circuit area.

### CITATION LIST

### PATENT LITERATURE

[PTL 1] U.S. Patent Application Publication No. 2022/0068921

[PTL 2] U.S. Patent Application Publication No. 2023/0178435

[PTL 3] U.S. Patent Application Publication No. 2023/0067311

[PTL 4] U.S. Patent Application Publication No. 2022/0123023

[PTL 5] U.S. Patent Application Publication No. 2022/0181258

[PTL 6] WO 2020/065916

[PTL 7] WO 2020/066797

[PTL 8] WO 2020/217396

[PTL 9] WO 2020/217400

[PTL 10] U.S. Patent Application Publication No. 2021/0366902

[PTL 11] U.S. Patent Application Publication No. 2022/0102479

[PTL 12] U.S. Patent Application Publication No. 2021/0210600

[PTL 13] U.S. Patent No. 10950546

[PTL 14] U.S. Patent No. 11004789

### SUMMARY OF THE INVENTION

A semiconductor device includes a substrate, a first cell including a first power supply line extending in a first direction in plan view on a first surface of the substrate, a first complementary field effect transistor (CFET) including a first transistor disposed on a second surface of the substrate opposite to the first surface at a position overlapping with the first power supply line in plan view, and a second transistor disposed above the first transistor, a first conductive wall extending in the first direction and disposed offset from the first power supply line in a second direction different from the first direction in plan view, and a first interconnect extending in the second direction and connected to the first transistor, and a second cell adjacent to the first cell in the second direction, the second cell including a second power supply line extending in the first direction on the first surface, a second CFET including a third transistor disposed on the second surface at a position overlapping with the second power supply line in plan view, and a fourth transistor disposed above the third transistor, a second conductive wall extending in the first direction and disposed offset from the second power supply line in the second direction, and a second interconnect extending in the second direction and connected to the third transistor, wherein the first interconnect and the second interconnect are arranged in a staggered manner in the first direction.

In a semiconductor device having a circuit for supplying power to the CFET with a conductive wall perpendicular to the substrate, a semiconductor device having a structure capable of reducing a circuit area is achieved.

### BRIEF DESCRIPTION OF THE DRAWINGS

FIG. 1 is a schematic diagram illustrating an outline of a layout of a semiconductor device according to an embodiment;

FIG. 2 is a schematic cross-sectional view illustrating an example of an interconnect structure of a circuit region of the semiconductor device;

FIG. 3 is a drawing illustrating an outline of a circuit of the semiconductor device according to the embodiment;

FIG. 4 is a plan view illustrating a basic configuration of a cell of the semiconductor device according to the embodiment;

FIG. 5 is a plan view illustrating top layers of cells adjacent to each other in a Y-direction;

FIG. 6 is a plan view illustrating bottom layers of cells adjacent to each other in the Y-direction;

FIG. 7 is a cross-sectional view of FIGS. 5 and 6 taken along a line X1-X1′;

FIG. 8 is a cross-sectional view of FIGS. 5 and 6 taken along a line Y1-Y1′; and

FIG. 9 is a drawing illustrating a modification example of the semiconductor device.

### DESCRIPTION OF THE PREFERRED EMBODIMENTS

In an embodiment, in a semiconductor device in which a power supply voltage is supplied to a CFET through a power wall perpendicular to the substrate, a reduction in circuit area is achieved by devising routing of a drain signal of a bottom transistor. In the following, a specific configuration of the semiconductor device of the present embodiment will be described with reference to the accompanying drawings. In addition, the embodiments described below are not intended to limit the invention but are examples, and all features and combinations thereof described in the embodiments are not necessarily essential to the invention. The sizes and positional relationships of the components shown in the drawings may be exaggerated to facilitate understanding of the invention. In the drawings, the same constituent elements are denoted with the same reference numerals, and redundant description thereabout may be omitted.

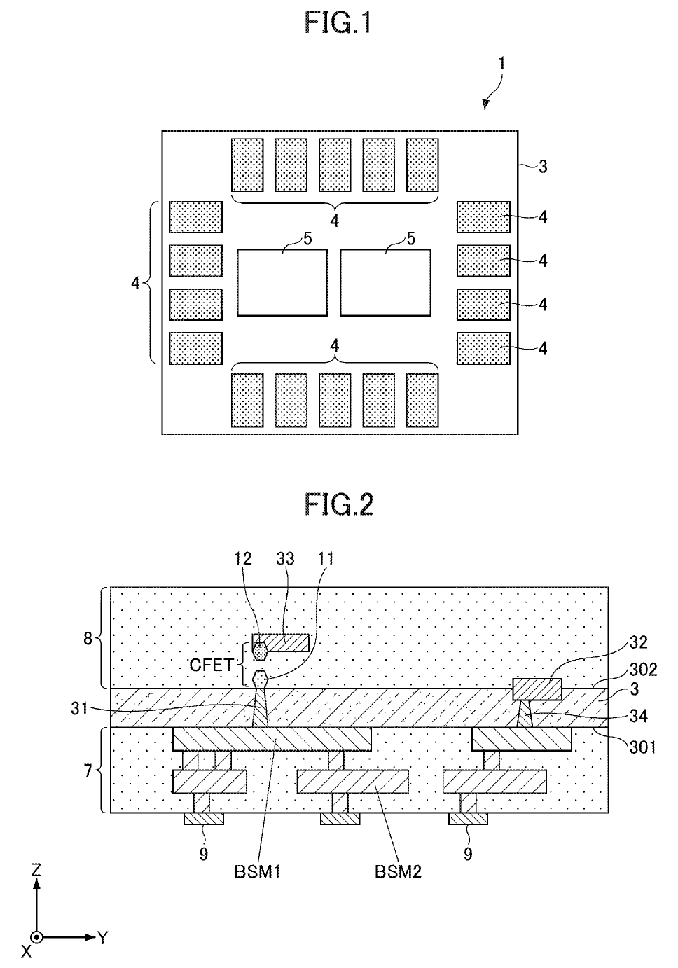

FIG. 1 is a schematic diagram illustrating an outline of a layout of a semiconductor device 1 according to the embodiment. The semiconductor device 1 has one or more circuit regions 5 provided on a substrate 3 and a plurality of input and output (I/O) cell regions 4 disposed thereon. The circuit region 5 may have a standard cell including a plurality of logic circuits, or may have other circuits such as a gate array, SRAM (Static Random Access Memory), and analog circuits.

FIG. 2 is a schematic cross-sectional view illustrating an example of an interconnect structure of the circuit region 5 of the semiconductor device 1. In a coordinate system of FIG. 2, a plane parallel to a substrate 3 is referred to as an XY-plane, and a direction perpendicular to the substrate 3, that is, a stacking direction is referred to as a Z-direction. The semiconductor device 1 has a first interconnect layer 7 on a back surface 301 of the substrate 3 and a second interconnect layer 8 on a front surface 302 of the substrate. The semiconductor device 1 supplies a power supply voltage from the back surface 301 of the substrate 3 to a circuit on the front surface 302 side of the substrate 3. Here, the back surface 301 of the substrate 3 is referred to as a “first surface” and the front surface 302 is referred to as a “second surface”. A CFET in which a first transistor 11 and a second transistor 12 are stacked in a direction perpendicular to the substrate 3 is disposed on the front surface 302 of the substrate 3. The lower first transistor 11 may be referred to as a “bottom transistor” and the upper second transistor may be referred to as a “top transistor”. In the present figure, sources and drains (hereinafter referred to as “source/drain”, as appropriate) of the first transistor 11 and the second transistor 12 are arranged in an X-direction perpendicular to the drawing.

In the first interconnect layer 7, a power supply interconnect for supplying an operating voltage of a circuit or a reference voltage lower than the operating voltage is formed. In the example shown in FIG. 2, a first layer interconnect (BSM1) on the back surface 301 of the substrate 3 and a second layer interconnect (BSM2) on the back surface 301 are provided. A pad 9 serving as an external connection terminal is formed on the lowermost surface of the first interconnect layer 7. The first interconnect layer 7 may be an interconnect layer formed directly on the back surface 301 of the substrate 3 or an interconnect layer formed on another chip (i.e., a substrate) bonded to the back surface 301 of the substrate 3.

The interconnects BSM1 and BSM2 of the first interconnect layer 7 are connected to the semiconductor layer of the first transistor 11 of the CFET via a through via 31 penetrating the substrate 3. The interconnects BSM1 and BSM2 of the first interconnect layer 7 are connected to the source of the second transistor 12 of the CFET via through vias (not shown) provided in the substrate 3 and interconnects 33 formed in the second interconnect layer 8. An embedded interconnect 32 connected to a through via 34 may be provided on the front surface 302 side of the substrate 3. The connection between the interconnects on the back surface 301 of the substrate 3 and the second transistor 12 on an upper side of the CFET may be achieved, as will be described later, by a conductive wall (also referred to as a “power wall”) extending vertically from the back surface 301 toward the front surface 302 of the substrate 3 and interconnects 33 connected to the conductive wall.

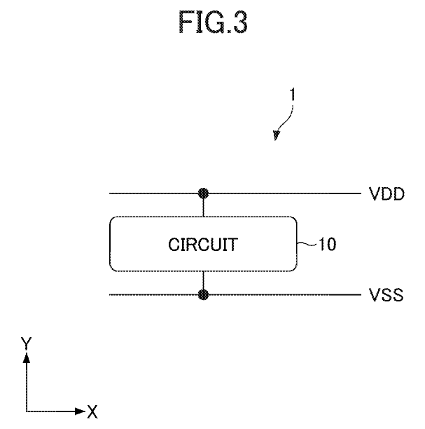

FIG. 3 is a drawing illustrating an outline of a circuit of the semiconductor device 1 according to the embodiment. Each circuit 10 arranged in the circuit region 5 (see FIG. 1) of the semiconductor device 1 is connected to two power supply lines VDD and VSS, and operates by receiving power from the power supply lines VDD and VSS. The circuit 10 may be a standard cell having a plurality of logic circuits as described above or may be a circuit other than a standard cell. On the substrate 3, a large number of circuits connected to the power supply lines VDD and VSS may be arranged in the X-direction or Y-direction in a one-dimensional or two-dimensional matrix. In the configuration in which the power supply voltage is supplied to the CFET included in the circuit 10 by a BS-PDN, in order to downsize the cell area of the circuit 10 as much as possible or to increase circuit density as much as possible, it is preferable to devise a connection relationship between the power supply lines VDD and VSS and elements included in the circuit 10.

### BASIC CONFIGURATION OF CELL OF EMBODIMENT

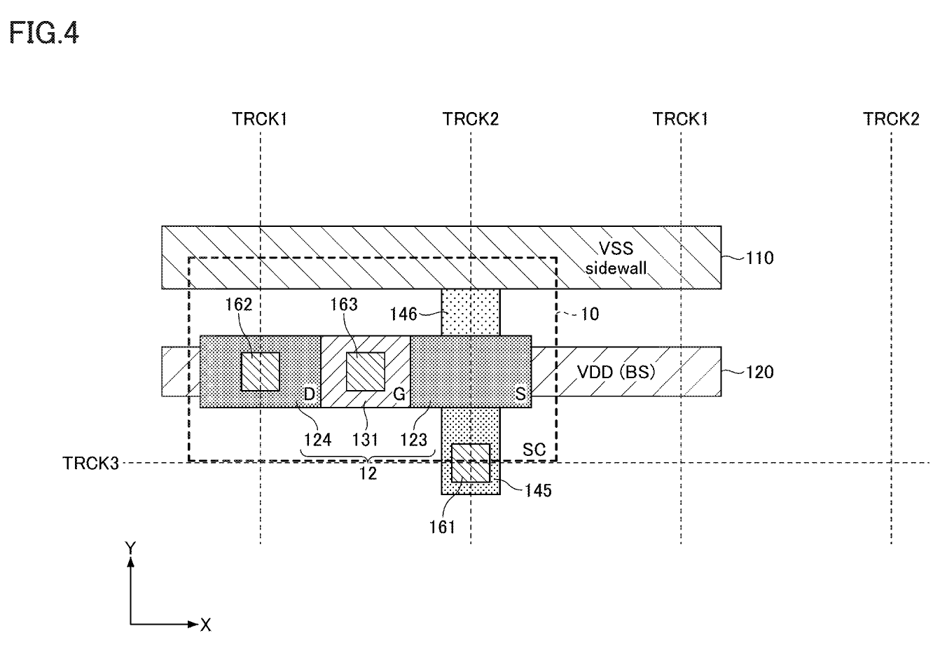

FIG. 4 is a plan view illustrating a basic configuration of the semiconductor device 1 according to the embodiment. The plane parallel to the substrate 3 (see FIG. 2) is referred to as an XY-plane. In the following description, a circuit 10 of a minimum unit including a CFET is referred to as a standard cell (SC) or simply a “cell 10”. The cell 10 includes, for example, one CFET, a high-voltage-side power supply line (VDD) for supplying a power supply voltage to the CFET, and a low voltage side power supply line (VSS).

A power supply line (VDD) 120 extending in a first direction (e.g., X-direction) is provided on the back surface side of the substrate 3. A power supply line 110 extending in the same direction as the power supply line (VDD) 120 and supplying a low voltage side reference voltage is provided on the front surface side of the substrate 3 at a predetermined interval from the power supply line (VDD) 120 in a second direction (e.g., Y-direction). The power supply line 110 is a conductive wall that extends from the back surface of the substrate to the height of the second transistor 12 of the CFET on the front surface side through the substrate 3. In this sense, the power supply line 110 is hereinafter referred to as a “VSS sidewall 110”. The VSS sidewall 110 may be a conductive wall that extends from the front surface of the substrate 3 to the height of the second transistor 12 of the CFET. In this case, a through via formed in the substrate 3 may be connected to the VSS sidewall 110, and a reference voltage on the low voltage side may be supplied to the VSS sidewall 110 via the through via. Further, the VSS sidewall 110 may be a conductive wall that extends to a position higher than the second transistor 12 of the CFET. A VDD sidewall to which an operating voltage is supplied may be disposed in place of the VSS sidewall 110, and a power supply line to which a reference voltage on the low voltage side is supplied may be disposed on the back surface of the substrate 3.

A CFET is formed by stacking the first transistor 11 (see FIG. 2) and the second transistor 12 in the height direction at a position overlapping the power supply line (VDD) 120 in plan view on the front surface side of the substrate 3. In the plan view of FIG. 4, only the upper second transistor 12 is seen, but the first transistor 11 is disposed below the second transistor 12. The second transistor 12 has a gate 131, and a source 123 and a drain 124 provided on respective sides of the gate 131 in the X-direction. The gate 131 extends in a direction perpendicular to the XY-plane and is commonly used for the first transistor 11 and the second transistor 12.

As an example, the second transistor 12 is an n-type field effect transistor (nFET), and an n-type impurity is added to a semiconductor layer where the source 123 and the drain 124 are formed. The first transistor 11 below the second transistor 12 is a p-type field effect transistor (pFET), and a p-type impurity is added to a semiconductor layer where the source/drain are formed. Materials of the semiconductor layers of the first transistor 11 and the second transistor 12 may be the same or different. For example, Ge may be used for the semiconductor layer where the source/drain of the first transistor 11 used as pMOS is formed to increase hole mobility, and Si may be used for the semiconductor layer where the source/drain of the second transistor 12 used as nMOS is formed. As will be described later, the first transistor 11 and the second transistor 12 are each provided with a channel of a nanosheet for connecting the source/drain.

In the configuration example of FIG. 4, the drain of the first transistor 11 is disposed below the source 123 of the second transistor 12, and the source of the first transistor 11 is disposed below the drain 124 of the second transistor 12. The source of the first transistor 11 is connected to a power supply line (VDD) 120 via a through via 31 (see FIG. 2) penetrating the substrate 3, and a signal of the first transistor 11 is routed via an interconnect 145 protruding in a -Y-direction from the drain of the first transistor 11. The signal of the first transistor 11 is routed from the interconnect 145 to the upper interconnect layer via a via plug 161. The signal of the second transistor 12 is routed from the drain 124 to the upper interconnect layer via a via plug 162. In the present disclosure, the direction indicated by an arrow showing the X-direction or the Y-direction in the drawings is referred to as a plus (+) direction, and the opposite direction is referred to as a minus (−) direction.

A plurality of cells 10 can be arranged in the X-direction in which the power supply line (VDD) 120 and the VSS sidewall 110 extend, the Y-direction, or both. In accordance with the arrangement of the plurality of cells 10, a track for routing a signal from each cell 10 is provided. In a case where a plurality of cells 10 are arranged in the X-direction and tracks 1 (TRCK1) and 2 (TRCK2) extending in the Y-direction are alternately provided from the left side of the drawing, the interconnect 145 for routing a signal from the lower first transistor 11 in each cell 10 is arranged on every other track, that is, on either track 1 or track 2. In FIG. 4, the signal of the first transistor 11 is routed in track 2, but this is not limited to this example, and the signal of the first transistor 11 may be routed from track 1 in each cell 10 in a case of being in every other track.

Additionally, the source 123 of the upper second transistor 12 is connected to the VSS sidewall 110 via an interconnect 146. The drain 124 of the second transistor 12 is connected to the upper interconnect layer via the via plug 162, and the signal of the second transistor 12 is routed. In the arrangement shown in FIG. 4, both the interconnect 145 for routing the signal from the first transistor 11 and the interconnect 146 for connecting the second transistor 12 to the VSS sidewall 110 are arranged on even-numbered tracks. The signal of the second transistor 12 is routed to the upper interconnect layer via the via plug 162 of track 1.

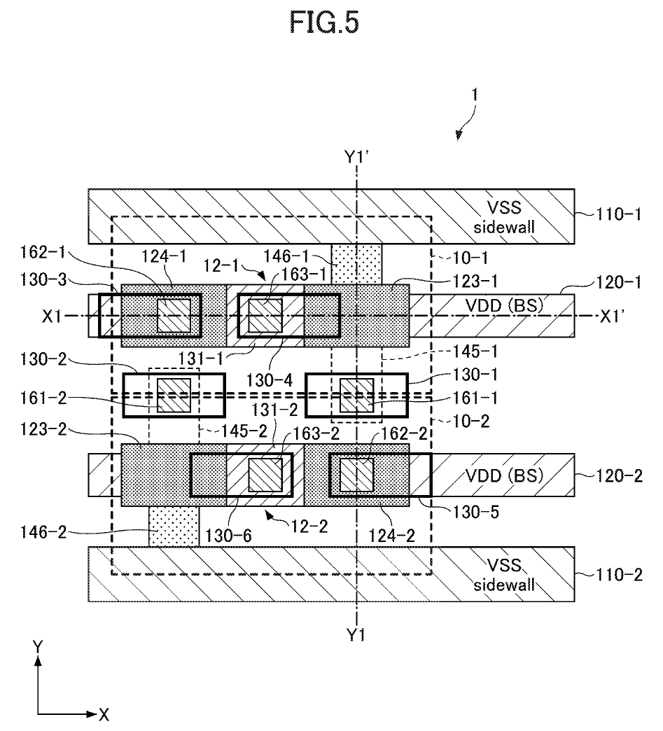

In a case of the interconnect 145 for routing the signal from the first transistor 11 being arranged on every other track, the interconnect 145 and the interconnect 146 need not be arranged on the same track. For example, the drain of the first transistor 11 may be arranged below the drain 124, and the interconnect 145 and the interconnect 146 may be arranged in a staggered manner on respective sides of the power supply line (VDD) 120 in plan view. By arranging the interconnects 145 for routing the signal from the first transistor 11 on every other track, it is possible to prevent the respective interconnects 145 of the cells adjacent in the Y-direction from being arranged adjacent in the Y-direction. Therefore, it is possible to narrow the interval between the first transistor 11 and the second transistor 12 of the cells adjacent in the Y-direction, which achieves downsizing or a high density of the cells 10. Specifically, as will be described with reference to FIG. 5 and thereafter, the interconnect 145 for routing the signal of the first transistor 11 from the cells adjacent in the Y-direction may be arranged on the same track 3 (TRCK3) extending in the X-direction.

### ARRANGEMENT CONFIGURATION BETWEEN ADJACENT CELLS

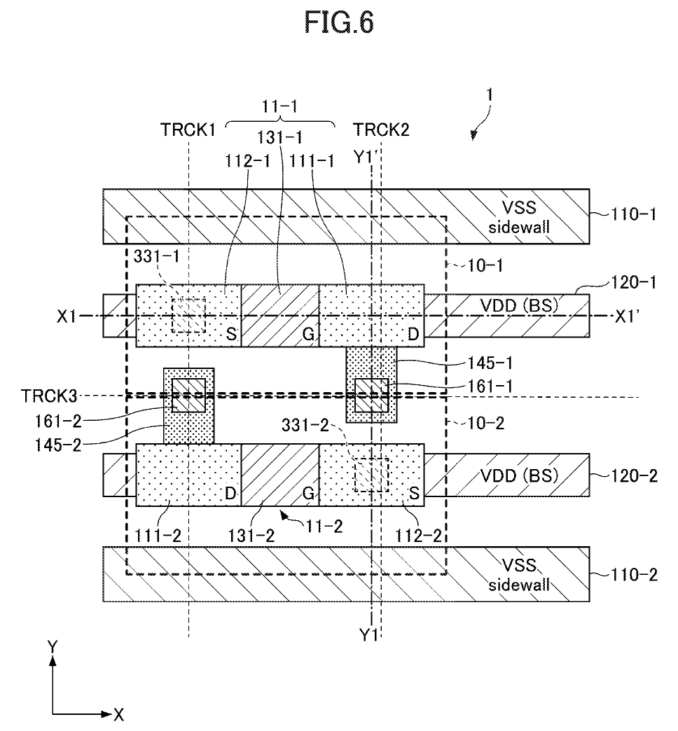

FIG. 5 is a plan view illustrating top layers of CFETs of a first cell 10-1 and a second cell 10-2 adjacent to each other in the Y-direction, and FIG. 6 is a plan view illustrating bottom layers of the CFETs of the first cell 10-1 and the second cell 10-2 adjacent to each other in the Y-direction. The top layer of the CFET is a layer including an upper second transistor 12, and the bottom layer is a layer including a lower first transistor 11.

The first cell 10-1 has a first power supply line 120-1 extending in a first direction (e.g., X-direction) on the back surface 301 of the substrate 3 (see FIG. 2), and a first VSS sidewall 110-1 extending in the X-direction and provided at a predetermined interval from the first power supply line 120-1 in the second direction (e.g., +Y-direction). A first CFET includes a first transistor 11-1 and a second transistor 12-1 stacked in a direction perpendicular to the substrate 3 on the front surface 302 side of the substrate 3 at a position overlapping the first power supply line 120-1 in plan view. The first VSS sidewall 110-1 has a height reaching the height of the second transistor 12-1 of the first CFET.

A second cell 10-2 adjacent to the first cell 10-1 in the -Y-direction has a second power supply line 120-2 extending in the X-direction, and a second VSS sidewall 110-2 extending in the X-direction and provided at a predetermined interval from the second power supply line 120-2 in the -Y-direction. A second CFET includes a third transistor 11-2 and a fourth transistor 12-2 stacked in a direction perpendicular to the substrate 3 on the front surface 302 side of the substrate 3 at a position overlapping the second power supply line 120-2 in plan view. The second VSS sidewall 110-2 has a height reaching the height of the fourth transistor 12-2 of the second CFET.

In the two adjacent cells 10-1 and 10-2 in the Y-direction, the power supply lines extending in the X-direction are arranged in an order of VSS, VDD, VDD, and VSS.

As shown in the bottom layer of FIG. 6, the interconnects 145-1 are drawn in the -Y-direction from a drain 111-1 of the first transistor 11-1 of the first cell 10-1 to extract the first signal. The interconnects 145-2 are drawn in the opposite direction (+Y-direction) to the interconnects 145-1 from a drain 111-2 of the third transistor 11-2 of the second cell 10-2 to extract the second signal. The interconnects 145-1 and 145-2 are arranged in a staggered manner along the same track extending in the X-direction between the first cell 10-1 and the second cell 10-2.

For example, if the interconnects 145-1 of the first cell 10-1 are arranged in the even-numbered track (TRCK2) of the tracks arranged in the X-direction, the interconnects 145-2 of the second cell 10-2 are arranged in the odd-numbered track (TRCK1) at the same position in the Y-direction. Thus, track 3 (TRCK3) extending in the X-direction can be shared between the first cell 10-1 and the second cell 10-2, and the number of tracks arranged side by side in the Y-direction can be reduced.

A source 112-1 of the first transistor 11-1 of the first cell 10-1 receives the operating voltage directly from the first power supply line 120-1 on the back surface 301 of the substrate 3 via a through via 331-1 penetrating the substrate 3. A source 112-2 of the third transistor 11-2 of the second cell 10-2 receives the operating voltage directly from the second power supply line 120-2 via a through via 331-2 penetrating the substrate 3.

Referring back to FIG. 5, in the top layer, the second transistor 12-1 of the first cell 10-1 has a source 123-1 and a drain 124-1 disposed on respective sides of a gate 131-1. The gate 131-1 is used in common with the first transistor 11-1. The source 123-1 of the second transistor 12-1 is connected to the first VSS sidewall 110-1 via an interconnect 146-1. The drain 124-1 of the second transistor 12-1 is connected to an interconnect 130-3 in a higher layer via a via plug 162-1. A gate signal is input to the gate 131-1 from an interconnect 130-4 in a higher layer through a via plug 163-1.

The fourth transistor 12-2 of the second cell 10-2 has a source 123-2 and a drain 124-2 arranged on respective sides of a gate 131-2. The gate 131-2 is used in common with the third transistor 11-2. The source 123-2 of the fourth transistor 12-2 is connected to the second VSS sidewall 110-2 via an interconnect 146-2. The drain 124-2 of the fourth transistor 12-2 is connected to an interconnect 130-5 of a higher layer via a via plug 162-2. A gate signal from an interconnect 130-6 of a higher layer is input to the gate 131-2 via a via plug 163-2.

An interconnect 145-1 protruding in the -Y-direction from the first transistor 11-1 in the bottom layer (shown by a broken line in FIG. 5) is connected to an interconnect 130-1 of a higher layer via a via plug 161-1. An interconnect 145-2 protruding in the +Y-direction from the third transistor 11-2 in the bottom layer is connected to an interconnect 130-2 of a higher layer via a via plug 161-2. With this configuration, the signal of the first transistor 11-1 and the signal of the third transistor 11-2 can be routed by a single track extending in the X-direction at a boundary between the first cell 10-1 and the second cell 10-2 adjacent in the Y-direction. As a result, the interval between the first cell 10-1 and the second cell 10-2, more specifically, the interval between the CFET of the first cell 10-1 and the CFET of the second cell 10-2, can be reduced to increase the circuit density. In each of the cells 10, the signal of the second transistor 12 in the upper layer is routed directly to the upper interconnect layer via the corresponding via plug 162, which prevents an increase in circuit size. Note that one or both of the interconnect 145-1 and the interconnect 145-2 need not be arranged depending on the type of the circuit arranged in each cell 10.

### CROSS-SECTIONAL STRUCTURE

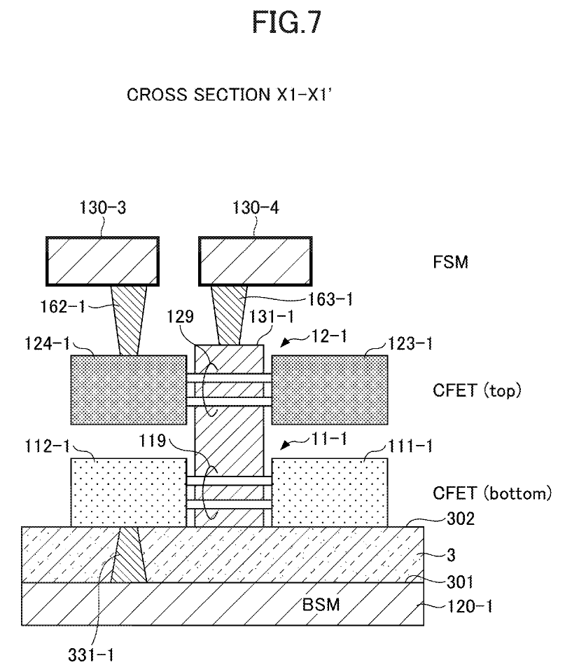

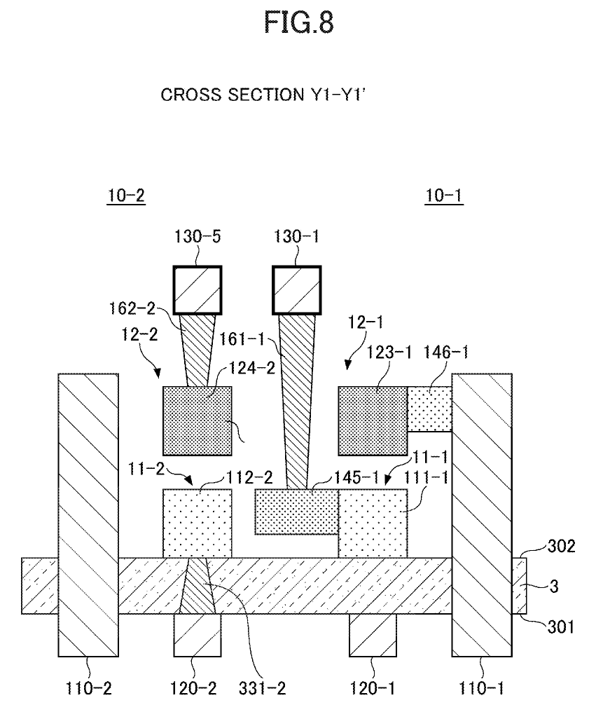

FIG. 7 is a cross-sectional view of FIGS. 5 and 6 taken along a line X1-X1′, and FIG. 8 is a cross-sectional view of FIGS. 5 and 6 taken along a line Y1-Y1′.

The cross section X1-X1′ is a vertical cross section taken along the first power supply line 120-1. The cross section Y1-Y1′ is a vertical cross section taken along a line perpendicular to the line X1-X1′ and penetrating the signal extraction interconnect 145-1 of the first transistor 11-1.

In the cross section X1-X1′ of FIG. 7, a source 112 of the first transistor 11-1 is connected to the power supply line 120-1 on the back surface 301 of the substrate 3 via the through via 331-1 penetrating the substrate 3. Thus, the source 112 of the first transistor 11-1 is connected to the VDD. A drain 111 provided on the opposite side of the source 112 across the gate 131-1 is connected to the interconnect 145-1 (see FIG. 6) extending in a direction perpendicular to the drawing. The source 112 and the drain 111 are connected via a channel 119 made of a nanosheet.

The source 123 of the second transistor 12-1 is connected to the interconnect 146-1 (see FIG. 5) extending in a direction perpendicular to the drawing. The drain 124 is connected to the interconnect 130-3 on an upper layer via the via plug 162-1, and a signal of the second transistor 12-1 is routed. The source 123 and the drain 124 are connected via a channel 129 made of a nanosheet. The gate 131-1 extends to a height covering the height of the CFET on the front surface 302 of the substrate 3 and is commonly used for the first transistor 11-1 and the second transistor 12-1 to receive a gate signal from the interconnect 130-4 on an upper layer via the via plug 163-1.

In the cross section Y1-Y1′ of FIG. 8, the drain 111-1 of the first transistor 11-1 on the lower side of the first cell 10-1 is connected to the interconnect 145-1 and is connected to the interconnect 130-1 on an upper layer via the via plug 161-1. The source 123-1 of the second transistor 12-1 on the upper side is connected to the first VSS sidewall 110-1 penetrating the substrate 3 via the interconnect 146-1. The first power supply line 120-1 is connected to the source of the first transistor 11-1 at a position in a direction perpendicular to the drawing.

The source 112-2 of the third transistor 11-2 on the lower side of the second cell 10-2 is connected to the second power supply line 120-2 via the through via 331-2 penetrating the substrate 3. The drain 111-2 of the third transistor 11-2 is connected to the interconnect 145-2 (see FIG. 6) for routing the signal of the third transistor at a position in a direction perpendicular to the drawing. The interconnect 145-2 and the interconnect 145-1 of the first cell 10-1 are arranged in a staggered manner. The drain 124-2 of the fourth transistor 12-2 on the upper side is connected to the interconnect 130-5 on the upper layer via the via plug 162-2. The source of the fourth transistor 12-2 is connected to the interconnect 146-2 at a position in a direction perpendicular to the drawing (see FIG. 5) and is connected to the second VSS sidewall 110-2 penetrating the substrate 3.

As shown in the cross section Y1-Y1′ of FIG. 8, between the first cell 10-1 and the second cell 10-2 adjacent in the Y-direction, the signals of the first transistor 11-1 and the third transistor 11-2 on the lower layer are routed by track 3 extending in the X-direction. The interval between the first cell 10-1 and the second cell 10-2 can be narrowed, thereby improving the circuit density.

### MODIFICATION EXAMPLE

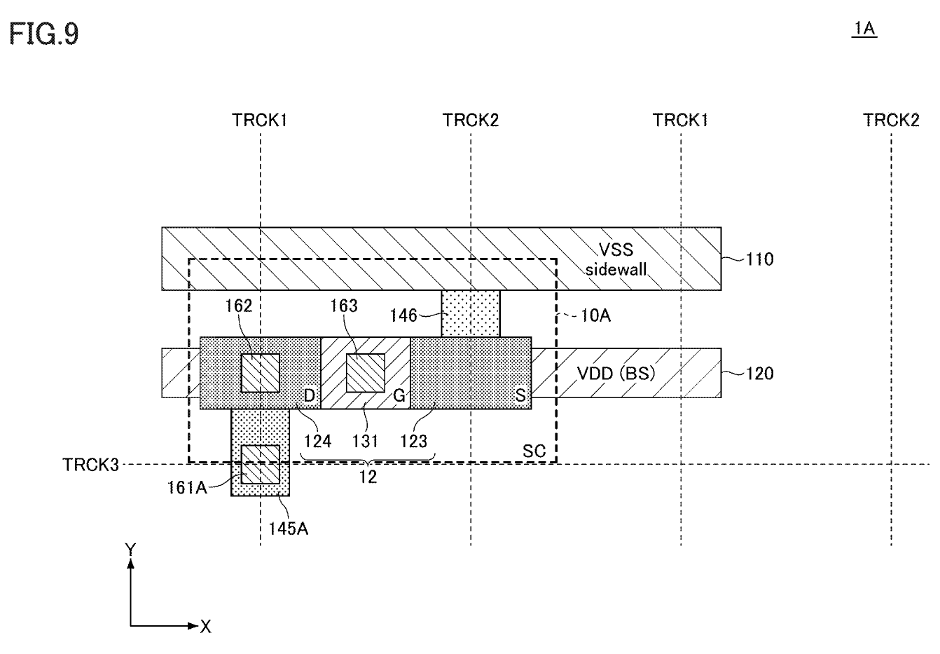

FIG. 9 is a drawing illustrating a basic configuration of a semiconductor device 1A as a modification example of the semiconductor device 1. In the above-described embodiment, the interconnect 145 for routing the signal of the lower first transistor 11 and the interconnect 146 for connecting the upper second transistor to the VSS are arranged on the same track (e.g., even-numbered track). In the modification, the interconnect 145 for routing the signal of the lower first transistor 11 and the interconnect 146 for connecting the upper second transistor to the ground potential are arranged on different tracks.

A power supply line (VDD) 120 extends in the X-direction on the back surface side of the substrate 3 (see FIG. 2). A VSS sidewall 110 extends in the X-direction from the power supply line (VDD) 120 at a predetermined interval in the Y-direction on the front surface side of the substrate 3. The first transistor 11 (see FIG. 2) and the second transistor 12 are stacked in the height direction on the front surface side of the substrate 3 at a position overlapping the power supply line (VDD) 120 in a plan view to form a CFET of the cell 10A. In the plan view of FIG. 9, only the upper second transistor 12 is seen, but the first transistor 11 is disposed below the second transistor 12. The second transistor 12 has the gate 131, and the source 123 and the drain 124 provided on respective sides of the gate 131 in the X-direction. The gate 131 extends in the direction perpendicular to the XY-plane and is commonly used for the first transistor 11 and the second transistor 12.

In the configuration example of FIG. 9, the source of the first transistor 11 is disposed below the source 123 of the second transistor 12, and the drain of the first transistor 11 is disposed below the drain 124 of the second transistor 12. The source of the first transistor 11 is connected to a power supply line (VDD) 120 via a through via (not shown) provided on track 2 (TRCK2). The drain of the first transistor 11 is connected to an interconnect 145A protruding in the -Y-direction, and a signal of the first transistor 11 is routed. The signal of the first transistor 11 is routed from the interconnect 145A to an upper layer interconnect via a via plug 161A. The signal of the second transistor 12 is routed to an upper layer interconnect via the via plug 162 connected to the drain 124 of the second transistor 12.

Also in the semiconductor device 1A, a large number of cells 10A can be arranged in a matrix in the X- and Y-directions. In each cell 10A arranged side by side in the X-direction, the interconnect 145A for routing a signal from the lower first transistor 11 is arranged on every other track, that is, track 1 (TRCK1) or track 2 (TRCK2). In FIG. 9, a signal of the first transistor 11 is routed via the interconnect 145A which is protruding in the -Y-direction on track 1 from the first transistor. In this case, a drain of a lower transistor of a cell adjacent in the Y-direction is connected to an interconnect protruding in the +Y-direction on track 2. That is, an interconnect for routing a signal of a lower transistor between the cells 10A adjacent in the Y-direction is arranged in a staggered manner on a common track 3 (TRCK3) extending in the X-direction.

The source 123 of the upper second transistor 12 is connected to the VSS sidewall 110 via the interconnect 146. The drain 124 of the second transistor 12 is connected to an interconnect on an upper layer via the via plug 162, and a signal of the second transistor 12 is routed. In the modified semiconductor device 1A, the interconnect 145A for routing a signal from the first transistor 11 and the interconnect 146 for connecting the second transistor 12 to the VSS sidewall 110 are arranged on different tracks. Additionally, a signal of the second transistor 12 is routed to an interconnect on an upper layer via the via plug 162 on an odd track, and a signal of the first transistor 11 and a signal of the second transistor 12 are routed on the same track.

Also in the arrangement shown in FIG. 9, the interconnect 145A for routing a signal from the first transistor 11 is arranged on every other track in the X-direction, and a signal from the first transistor can be routed from adjacent cells in the Y-direction by the same track 3 (TRCK3) extending in the X-direction. In the circuit where the CFET is supplied with a power supply voltage from the VSS sidewall 110, the interconnect layout is simplified, and the cell 10A can be downsized or densified.

Further, the present invention is not limited to these embodiments, and various variations and modifications may be made without departing from the scope of the present invention. For example, in FIG. 5, the first cell 10-1 and the second cell 10-2 adjacent in the Y-direction are arranged in point symmetry or rotation symmetry with respect to the intermediate point between the via plugs 161-1 and 161-2 for routing a signal from the first transistor 11 in the lower layer, but the arrangement need not be point symmetry. If the via plugs 161-1 and 161-2 are arranged on the same track extending in the X-direction, the interconnect 146-1 connected to the first VSS sidewall 110-1 at the first cell 10-1 and the interconnect 146-2 connected to the second VSS sidewall 110-2 at the second cell 10-2 may be arranged on the same track extending in the Y-direction. Alternatively, the via plug 162-1 for routing a signal from the second transistor 12-1 to the upper layer at the first cell 10-1 and the via plug 162-2 for routing a signal from the fourth transistor 12-2 at the second cell 10-2 may be arranged on the same track extending in the Y-direction. Further, the via plugs 161-1 and 161-2 may be arranged at positions shifted in the Y-direction. The direction of the shift in the Y-direction may be the same or different. For example, the via plugs 161-1 and 161-2 may be shifted in opposite directions along the Y axis. The VSS may be a ground potential or a reference potential other than the ground potential and lower than the VDD. The configuration of the present disclosure is applicable to any circuit or device that supplies a power supply voltage to the CFET with a VSS sidewall or a power wall.

What is claimed is:

1. A semiconductor device comprising:
a substrate;
a first cell including:
a first power supply line extending in a first direction in plan view on a first surface of the substrate;
a first complementary field effect transistor (CFET) including:
a first transistor disposed on a second surface of the substrate opposite to the first surface at a position overlapping with the first power supply line in plan view; and
a second transistor disposed above the first transistor;
a first conductive wall extending in the first direction and disposed offset from the first power supply line in a second direction different from the first direction in plan view; and
a first interconnect extending in the second direction and connected to the first transistor; and
a second cell adjacent to the first cell in the second direction, the second cell including:
a second power supply line extending in the first direction on the first surface;
a second CFET including:
a third transistor disposed on the second surface at a position overlapping with the second power supply line in plan view; and
a fourth transistor disposed above the third transistor;
a second conductive wall extending in the first direction and disposed offset from the second power supply line in the second direction; and
a second interconnect extending in the second direction and connected to the third transistor,
wherein the first interconnect and the second interconnect are arranged in a staggered manner in the first direction.

2. The semiconductor device according to claim 1, wherein:
the first interconnect is disposed on one of a first track or a second track, the first track and the second track being arranged side by side in the first direction and each extending in the second direction; and
the second interconnect is disposed on another one of the first track or the second track.

3. The semiconductor device according to claim 1, further comprising:
a first semiconductor layer and a second semiconductor layer disposed on the second surface of the substrate, arranged side by side in the first direction;
a third semiconductor layer disposed above the first semiconductor layer;
a fourth semiconductor layer disposed above the second semiconductor layer;
a first gate disposed between the first semiconductor layer and the second semiconductor layer and between the third semiconductor layer and the fourth semiconductor layer;
a fifth semiconductor layer and a sixth semiconductor layer disposed on the second surface of the substrate, arranged side by side in the first direction;
a seventh semiconductor layer disposed above the fifth semiconductor layer;
an eighth semiconductor layer disposed above the sixth semiconductor layer; and
a second gate disposed between the fifth semiconductor layer and the sixth semiconductor layer and between the seventh semiconductor layer and the eighth semiconductor layer, wherein:
the first transistor includes the first semiconductor layer, the second semiconductor layer, and the first gate;
the second transistor includes the third semiconductor layer, the fourth semiconductor layer, and the first gate;
the third transistor includes the fifth semiconductor layer, the sixth semiconductor layer, and the second gate;
the fourth transistor includes the seventh semiconductor layer, the eighth semiconductor layer, and the second gate;
the first semiconductor layer and the sixth semiconductor layer are arranged side by side in the second direction;
the second semiconductor layer and the fifth semiconductor layer are arranged side by side in the second direction;
the first interconnect is connected to the first semiconductor layer; and
the second interconnect is connected to the fifth semiconductor layer.

4. The semiconductor device according to claim 3, further comprising:
a third interconnect extending in the second direction and being connected to the first conductive wall and to one of the third semiconductor layer or the fourth semiconductor layer; and
a fourth interconnect extending in the second direction and being connected to the second conductive wall and to one of the seventh semiconductor layer or the eighth semiconductor layer.

5. The semiconductor device according to claim 3, further comprising:
a first through via formed in the substrate and connected to the first power supply line and the second semiconductor layer; and
a second through via formed in the substrate and connected to the second power supply line and the sixth semiconductor layer.

6. The semiconductor device according to claim 4, wherein:
the third interconnect is connected to the fourth semiconductor layer; and
the fourth interconnect is connected to the seventh semiconductor layer.

7. The semiconductor device according to claim 4, wherein:
the third interconnect is connected to the third semiconductor layer; and
the fourth interconnect is connected to the seventh semiconductor layer.

8. The semiconductor device according to claim 1, wherein the first conductive wall, the first power supply line, the second power supply line, and the second conductive wall are sequentially disposed in the second direction.

9. The semiconductor device according to claim 1, wherein:
the first power supply line and the second power supply line are configured to supply an operating potential of a circuit; and
the first conductive wall and the second conductive wall are configured to provide a reference potential lower than the operating potential.
